(19) United States
(12) Patent Application Publication
(10) Pub. No.: US 2012/0073853 A1
(43) Pub. Date: Mar. 29, 2012

(54) ACCESS COVER FOR A HANDWELL AND THE LIKE AND METHOD OF USE THEREOF

(75) Inventors: Scott Penson Hickey, Niagara Falls (CA); Siegfried Niedermair, Sharon (CA)

(73) Assignee: TIERCON CORP., Stoney Creek (CA)

(21) Appl. No.: 12/891,512

(22) Filed: Sep. 27, 2010

(51) Int. Cl. H05K 5/03; B23P 19/00

(52) U.S. Cl. 174/66; 29/428

(57) ABSTRACT

An access cover for a hand well or hand hole comprises a top member having an upper surface, a lower surface and a perimeter, the lower surface being configured to inhibit radial outward migration of wires positioned in the hand well, wherein the top member is constructed from an electrical insulating material. A method of using the access cover is provided.

### FIELD

This invention relates to electric handwells, handholes and the like.

### INTRODUCTION

An electric handwell comprises a chamber in the ground in which electrical wiring may be connected together or through which electrical conduits may extend. The handwell has a removable cover so that a worker may access electrical conduits that extend therethrough and/or access electrical conductors therein. Handwells, which are akin to small manholes, are also sometimes referred to as handholes and pull boxes. As used herein, the term “handwell” is used to refer to any such construct.

Referring to FIG. 1, a typical handwell is exemplified. As shown therein, handwell 10 comprises a cylindrical vertically extending wall 12 defining an internal chamber 14. As exemplified, vertically extending wall 12 comprises concrete. The concrete wall is typically formed by providing a form (e.g. a sono tube), which is mounted in the ground and into which concrete may be poured.

Vertically extending wall 12 has an upper end 16 and a lower end 18 and may be of any desired length. Handwell 10 may be positioned in a sidewalk or road, which has an upper surface 22. An access cover 24 is removably mounted above chamber 14. Preferably, the upper surface 32 of access cover 24 is level or essentially level with upper surface 22. Typically, a liner ring 34 made of metal is provided. Access cover 24 may be seated on liner ring 34 and, accordingly, may be flush with upper surface 22. As exemplified, vertically extending wall 12 extends so as to be flush with surface 22 and upper surface 32. Liner ring 34 may be seated in a recess formed in vertically extending wall 12 and may be secured thereto by any means known in the art, such as one or more screws 36. For example, liner ring 34 may be seated in the wet concrete used to from wall 12. When the concrete has cured, one or more screws 36 may be installed. Alternately, for example if the upper end of wall 12 is below grade, a concrete slab (e.g., for a sidewalk) may be poured over wall 12. Re-bar may be used to secure wall 12 and the sidewalk slab together. In such a case, liner ring 34 may be seated in the wet concrete that is used to form the sidewalk slab during initial construction.

One or more openings 28 may be provided in vertically extending wall 12. A plurality of openings 28 may be provided, each of which may have an electrical conduit 26 extending thereto. Electrical conductors (e.g. wires) may extend through conduits 26 and the terminal ends of the wires may be connected together inside chamber 14.

Typically, access covers are constructed from cast metal. More recently, a lightweight plastic access cover has been proposed (see U.S. Pat. No. 7,361,834 Trangsrud et al). As set out in Trangsrud et al, an access cover is provided having a plurality of vertical channels that extend between the top and bottom walls whereby a type of internal corrugated structure is formed. As exemplified therein, the central portion of the lower surface of the access cover is generally flat and the outer annular region of the lower surface is angled upwardly towards the perimeter of the access member.

### SUMMARY

Over time, the electrical insulating coating on wires in a handwell may degrade. If the wires contact a conductive member of the handwell, e.g. a metal access cover as is traditionally used, a metal liner of the handwell or the concrete wall when the concrete wall is wet, stray electrical current may be conveyed to the surface. Any person or animal in the vicinity of the handwell may accordingly experience an electrical shock. This problem can be acerbated if the ground surrounding the handwell is wet due to a rainfall, an in-ground sprinkler system or the like or if the interior of the handwell is flooded.

While the use of a plastic access cover as disclosed in Trangsrud et al can prevent electrical currents being conducted to upper surface 32 of the access cover, the wires in the hand well may still transmit stray electrical currents such as via liner ring 34 (which is typically constructed from metal) or from contacting the vertical wall 12 of the handwell.

In accordance with an aspect of this invention, an access cover for a handwell is provided wherein the access cover is configured to reduce the likelihood of a person or animal standing on or adjacent the access cover receiving an electric shock from the wiring in a handwell. For example, the lower surface of the access cover may be configured to inhibit radial outward migration of wires positioned in the handwell. An example of such a construction is to provide the lower surface of the access cover with a raised central area such as by configuring the lower surface to be dome shaped. Accordingly, the arched walls forming the dome will inhibit wires positioned in the central portion of the handwell at a height proximate the lower surface of the access cover migrating outwardly. The arched walls provide an upwardly and inwardly extending surface that will tend to prevent wires migrating outwardly towards vertical wall 12.

In accordance with another aspect, the access wall may be provided with a depending wall, which may extend away from the lower surface of the access cover, so as to prevent or reduce the likelihood of wires in the handwell migrating to contact the sidewalls of the handwell. The deepening wall, which is constructed from an electrical insulating material, provides a liner between chamber 14 and at least an upper portion of vertical wall 12. Accordingly, even if the wires were to migrate towards vertical wall 12, the wires may tend to contact the depending wall thereby inhibiting the transmission of electrical current through vertical wall 12 and/or liner ring 34 to the exterior of the handwell.

Accordingly, in one aspect of this invention there is provided an access cover for a hand well or hand hole comprising:
(a) a top member having an upper surface, a lower surface and a perimeter, the lower surface being configured to inhibit radial outward migration of wires positioned in the hand well; and,
(b) a depending wall extending away from the lower surface of the top member and positioned inwardly from the perimeter, whereby a portion of the top member radially outwardly of the perimeter comprises a flange that extends outwardly from the depending wall
wherein the top member and depending wall are constructed from an electrical insulating material.

In one embodiment, the surface has a raised central portion. Preferably the lower surface is dome shaped.

In another embodiment, the lower surface comprises a plurality of depending ribs, the ribs having a radial inner end and a radial outer end. Preferably, the radial inner end of the ribs have a height and the radial outer end of the ribs have an increased height. Alternately, or in addition, the top member, the depending wall and the ribs are integrally molded.

In another embodiment, the access cover is integrally molded.

In another embodiment, the access cover further comprises an opening provided at a location in the top member for passage therethrough of a securing member. Preferably, the opening is provided in the flange and the depending wall is recessed inwardly at the location.

In another embodiment, the access cover is constructed from a thermoplastic or thermoset material.

In another embodiment, the access cover is constructed from polyurethane or polyamide.

In another embodiment, the upper surface is generally flat and is provided with traction members.

In accordance with another aspect, there is provided a method of reducing the incidence of electrical shock emanating from a hand well comprising:
(a) positioning terminal ends of electrical wires towards the centre of the hand well;
(b) providing an access cover constructed from an electrical insulating material and comprising:
   (i) a top member having an upper surface, a lower surface and a perimeter, the lower surface being configured to inhibit radial outward migration of wires positioned in the hand well; and,
   (ii) a depending wall extending away from the lower surface of the top member; and,
(c) positioning the access cover on the hand well whereby the depending wall is positioned inwardly of the hand well and the terminal ends are positioned inwardly of the depending wall.

In one embodiment, the lower surface has a raised central region and the method further comprises positioning the terminal ends in the raised central region.

In another embodiment, the method further comprises securing the access cover to the hand well at a location exterior to the depending wall. Preferably, the method further comprises providing an inward recess of the depending wall at the location.

In another embodiment, the method further comprises constructing the access cover from a thermoplastic or thermoset material.

In another embodiment, the method further comprises constructing the access cover from polyurethane or polyamide.

In another embodiment, the method further comprises removing an existing cover and installing a liner ring constructed from an electrical insulating material prior to step (c).

In another embodiment, the method further comprises providing the liner ring and the access cover with inter fitting members.

In accordance with another aspect, there is provided an access cover for a hand well or hand hole comprising a top member having an upper surface, a lower surface and a perimeter, the lower surface being configured to inhibit radial outward migration of wires positioned in the hand well, wherein the top member is constructed from an electrical insulating material.

In one embodiment, the lower surface has a raised central portion. Preferably, the lower surface is dome shaped.

In another embodiment, the lower surface comprises a plurality of depending ribs, the ribs having a radial inner end and a radial outer end. Preferably, the radial inner end of the ribs have a height and the radial outer end of the ribs have an increased height. Alternately, or in addition, the top member and the ribs are integrally molded.

In another embodiment, the access cover is integrally molded.

In another embodiment, an opening provided at a location in the top member for passage therethrough of a securing member. Preferably, the opening is provided in a flange.

In another embodiment, the access cover is constructed from a thermoplastic or thermoset material.

In another embodiment, the access cover is constructed from polyurethane or polyamide.

In another embodiment, the upper surface is generally flat and is provided with traction members.

In accordance with another aspect, there is provided a method of reducing the incidence of electrical shock emanating from a hand well comprising:
(a) positioning terminal ends of electrical wires towards the centre of the hand well;
(b) providing an access cover constructed from an electrical insulating material and comprising a top member having an upper surface, a lower surface and a perimeter, the lower surface being configured to inhibit radial outward migration of wires positioned in the hand well; and,
(c) positioning the access cover on the hand well.

In one embodiment, the lower surface has a raised central region and the method further comprises positioning the terminal ends in the raised central region.

In another embodiment, the method further comprises constructing the access cover from a thermoplastic or thermoset material.

In another embodiment, the method further comprises constructing the access cover from polyurethane or polyamide.

In another embodiment, the method further comprises removing an existing cover and installing a liner ring constructed from an electrical insulating material prior to step (c).

In another embodiment, the method further comprises providing the liner ring and the access cover with inter fitting members.

### DRAWINGS

Reference is made in the detailed description through the accompanying drawings in which:

FIG. 1 is a cross-sectional view of a prior art handwell;

FIG. 2 is an exploded view of a handwell access cover and a liner ring of a handwell;

FIG. 3 is a bottom plan view of the access cover of FIG. 2;

FIG. 4 is a side elevation view of the access cover of FIG. 3;

FIG. 5 is a side view of the access cover of FIG. 2 showing the interior detail of the access cover;

FIG. 6 is a perspective view from below of an access cover with wires shown in an installed position;

FIG. 7 is a cross section through an alternate access cover;

FIGS. 8-11 are a series of drawings exemplifying a method of installing the access cover shown in FIG. 7;

FIGS. 12-15 are a series of drawings exemplifying a method of installing the access cover shown in FIG. 7 and a new liner ring;

FIG. 16 is an exploded view of FIG. 15;

FIG. 17 is an alternate embodiment of FIG. 14 exemplifying the use of a liner with integrally formed barbs

FIG. 18 is a partially exploded view of from above of an inner cover and an outer cover showing interlocking recesses and raised portions; and,

FIG. 19 is a partially exploded view of from below of an inner cover and an outer cover showing interlocking recesses and raised portions.

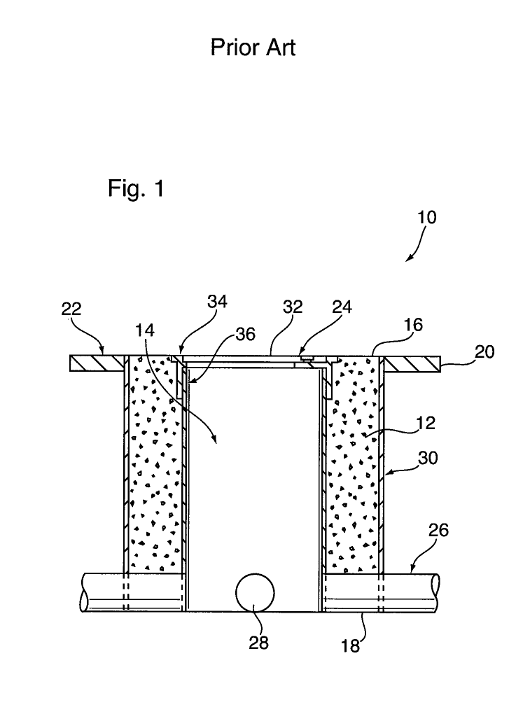

### DESCRIPTION OF VARIOUS EMBODIMENTS

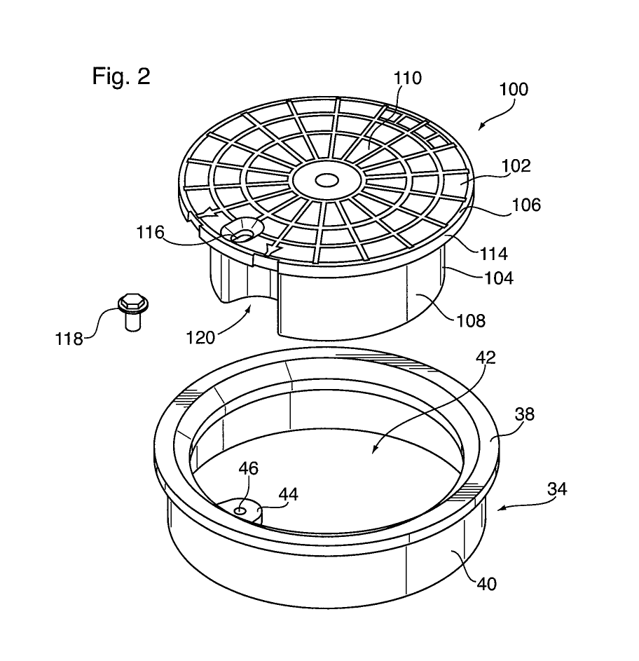

Referring to FIGS. 2-5, an access cover 100 is exemplified. Access cover 100 comprises a top member 102 and a depending wall 104, which has an outer surface 108. Top member 102 has an upper surface 110, a lower surface 112 and a perimeter 114. Top member 102 also comprises a portion positioned radially outwardly from depending wall 104, which comprises a flange 106. Accordingly, flange 106 extends between depending wall 104 and perimeter 114. Top member 102 is preferably planer and relatively thin. As exemplified, upper surface 110 of top member 102 may have a pattern or the like applied thereto so as to provide improved traction for pedestrians or cars.

Access cover 100 may be sized to fit in an existing handwell. As exemplified in FIG. 2, if handwell 10 has an existing liner ring 34, then access member may be sized to fit in the existing liner ring 34. Accordingly, flange 106 will extend over at least a portion of rim 38 of liner ring 34 and, preferably, extends to fully cover ring 38. Depending wall 108 of access cover 100 is positioned in opening 42 of liner ring 34 and is spaced inwardly from depending wall 40 of liner ring 34. Depending wall 108 is preferably positioned adjacent or touching depending wall 40. Accordingly, depending wall 108 will inhibit wires in handwell 10 from contacting depending wall 40.

Optionally, access cover 100 may be removably secured to the handwall by any means known in the art such as by one or more screws, integrally molded plastic bolts, integrally molded snap fits, and a quarter turn bayonet style lock. Preferably, as exemplified in FIGS. 2 and 16, top member 102 may be provided with an opening 116, which is positioned to align with opening 46 of flange 44 of ring 34. Opening 46 is preferably threaded so as to receive a securing member such as a bolt 118 that may extend through opening 116 and be received in threaded opening 46. It will be appreciated that other securing members may be utilized such as an integrally molded plastic bolt, an integrally molded snap fit, a quarter turn bayonet style lock. Further more than one securing member may be used.

Depending wall 108 may be a cylindrical wall positioned inwardly of opening 116. Such an embodiment might be utilized if, for example, opening 46 were positioned in rim 38 or in vertical wall 12. Alternately, as exemplified, if a flange 44 is provided, then depending wall 108 may be provided with a recess 120. Accordingly, when opening 116 is aligned with opening 46, recess 120 is aligned such that flange 44 may be received under top member 102 and not interfere with access member 100 being positioned in handwell 10. As exemplified, recess 120 is concave in shape. However, it will be appreciated that recess 120 may be of any particular shape provided flange 44 is receivable therein.

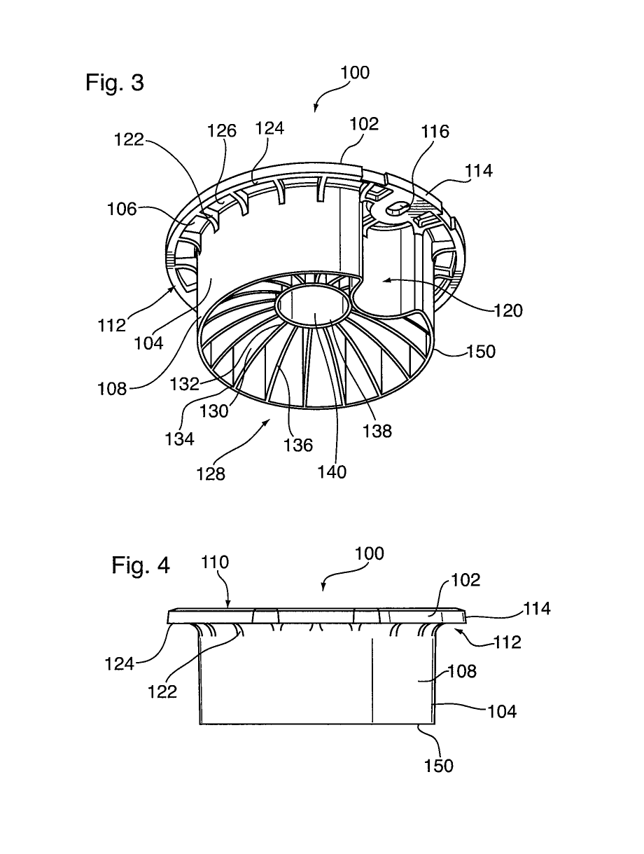

Optionally, as illustrated in FIGS. 3 and 4, a plurality of ribs 122 may be provided between depending wall 108 and perimeter 114 so as to increase the structural strength of flange 106. Referring to FIG. 3, perimeter 114 has a lower surface 124. A plurality of recesses 126 is provided on lower surface 112 of top member 102 (e.g. one recess 126 between a pair of spaced apart ribs 122). Ribs 122 are preferably configured so as to enable access cover 100 to seat properly on hand well 10. Alternately, lower surface 124 may be flat.

Lower surface 112 of access number 100 is configured to inhibit radial outward migration of wires 154 positioned in handwell 10. In a typical installation, the lower portion of a handwell is filled with dirt, gravel or the like. While conduits 26 may be provided at the lower end of handwell 10, the ends of wires 154 are preferably positioned towards the upper end of handwell 10 so as to facilitate a worker connecting the terminal ends 156 of wires 154 together and being able to service the wires as needed. During installation of access cover 100, the connected terminal ends 156 of wires 154 are preferably positioned adjacent the radial inner centre of handwell 10 and within raised central portion 128, e.g., dome shaped portion, of access cover 100.

By providing raised central area 128, the terminal ends of the wires would have to travel downwardly as well as outwardly prior to contacting vertical wall 12 of handwell 10. It will be appreciated that raised central portion 128 may be of various configurations. For example, it may comprise generally vertical sidewalls, angled sidewalls or, preferably, curved sidewalls. In any such configuration, downward movement of the terminal ends of the wires would be required for outward migration of the wires.

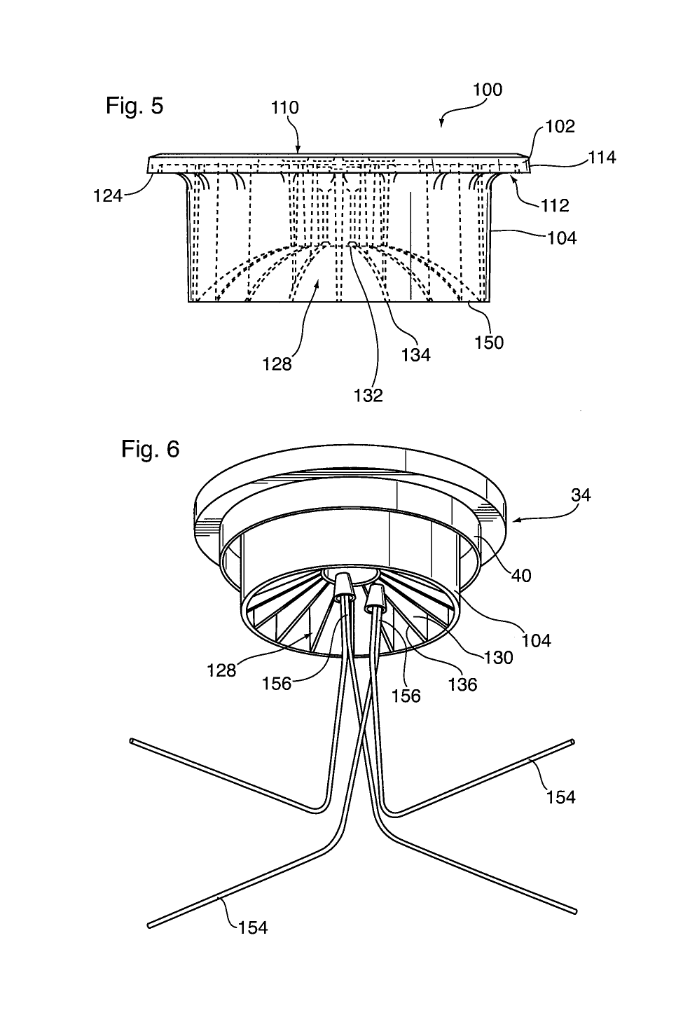

Referring to FIGS. 3 and 5, a preferred raised central portion 128 is exemplified. As exemplified therein, raised central portion 128 is dome shaped. The dome shape is defined by a plurality of ribs 130 that preferably extend downwardly from lower surface 112 of top member 102. Ribs 130 have a radial inner end 132, a radial outer end 134 and a lower surface 136, which is curved. Ribs 130 may extend all the way toward the radial inner centre of access cover 100. Alternately, as exemplified, they may terminate outwardly therefrom at a central hub 138. As exemplified, central hub 138 is defined by a circular depending wall 140 and is hollow. In an alternate embodiment, it will be appreciated that central hub 138 may be of any other configuration and may be solid or have a closed lower surface. In a further alternate embodiment, it will be appreciated that the space between adjacent lower surfaces 136 of ribs 130 may be solid so as to define a continuous dome surface. For example, a cover member (not shown) may be placed over the lower surface 136 of ribs 130.

As exemplified, radial outer ends 134 of ribs 130 terminate at the lower end of depending wall 108. In alternate embodiments, it will be appreciated that radial outer end 134 of ribs 130 may terminate at a position below depending wall 108 or, alternately upwardly form the lower surface of depending wall 108. Further, in an alternate embodiment, the upper end of ribs 130 may terminate at a distance spaced from lower surface 112 of top member 102. It will be appreciated that in addition to inhibiting the radial outward migration of wires positioned in the handwell, ribs 130 may also be designed to provide structural strength to access cover 100.

Depending wall 108 may of varying lengths. In a preferred embodiment, as exemplified in FIG. 6, depending wall 108 extends below depending wall 40 of liner ring 34. Accordingly, if liner ring 34 is made of metal and the wires are able to migrate towards vertical wall 12, depending wall 108 will essentially provide a liner adjacent depending wall 40 so as to inhibit the wires contacting the depending wall 40.

The cover and the depending wall are made from an electrical insulating material. Preferably, access cover 100 is made from an electrical insulating material. The electrical insulating material is preferably a thermoplastic or thermoset material. More preferably, these members are constructed from polyurethane or a polyamide. The thermoplastic or themoset materials may include various fillers, such as glass fibres, glass spheres, minerals and other non-conductive fillers. Various manufacturing methods may be utilized to manufacture the access cover, such as injection molding, injection-compression molding, roto-molding, and casting. The access cover is preferably manufactured by molding. Preferably, the depending wall and the ribs are integrally formed, e.g., molded. More preferably, the access cover itself (top member 102, depending wall 104, flange 106 and ribs 130) is integrally formed, e.g., molded.

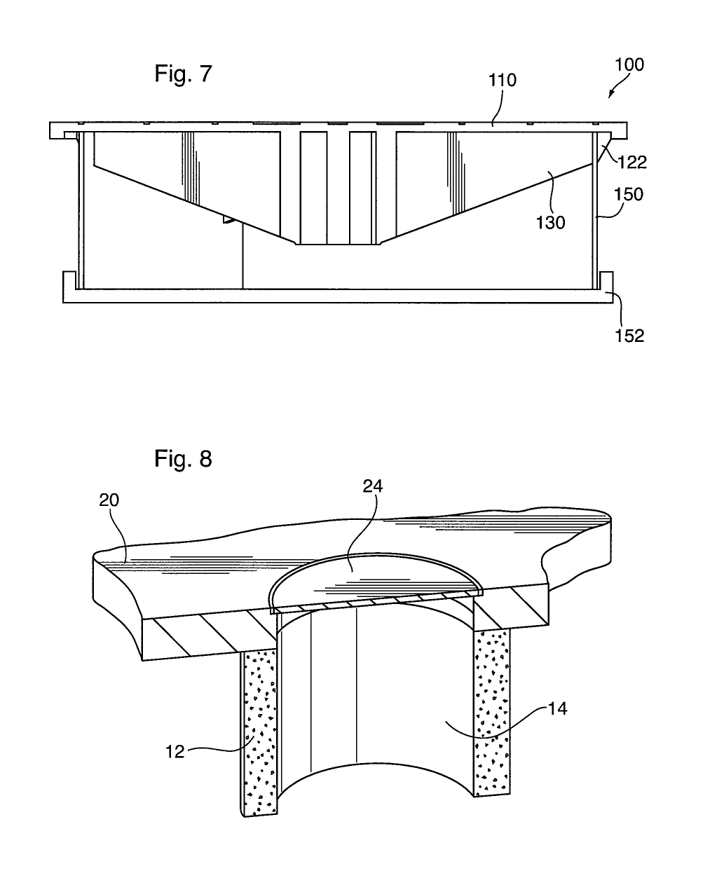

As exemplified in FIG. 7, a reinforcing member 152_may optionally be provided on or adjacent lower end 150 of depending wall 104 to provide enhanced strength and structural integrity of the depending wall. For example, as exemplified, an annular band 152 may be provided on lower end 150 of depending wall 104. Annular ring 152 may be manufactured by injection molding, injection compression molding, compression molding, roto molding, machined from a single block of material or the like and may be made of any material that is used to manufacture access cover 100. It could also be made as two halves and held together with non-metallic fasteners. Alternately, the width of the lower end may be increased. As shown in this alternate embodiment, ribs 130 extend upwardly from the centre of access cover 100 to depending wall 104.

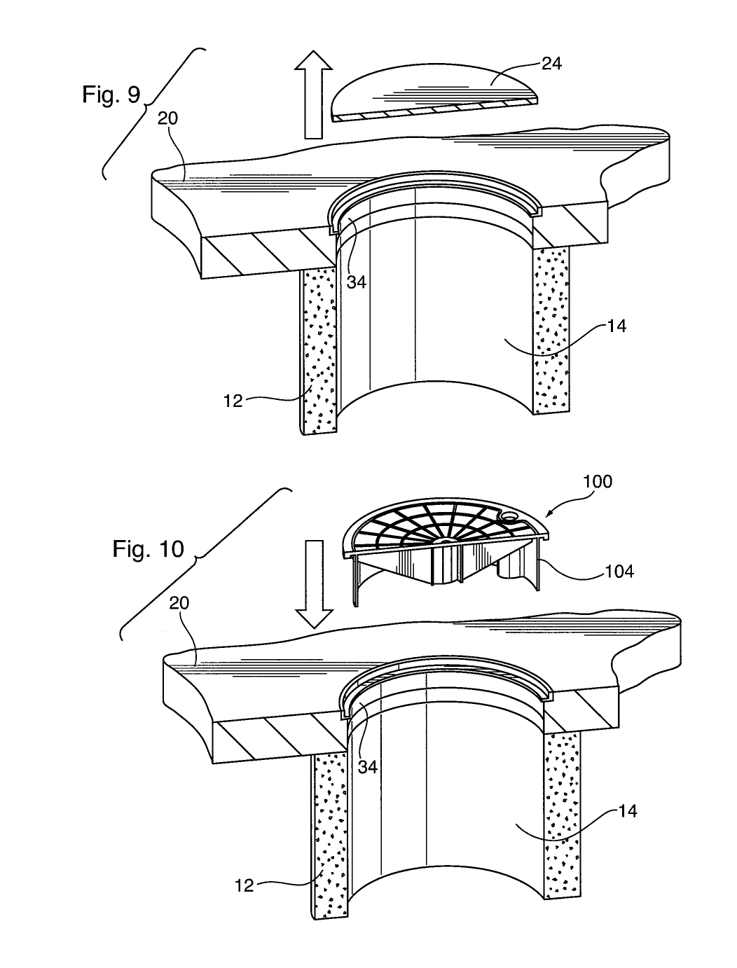

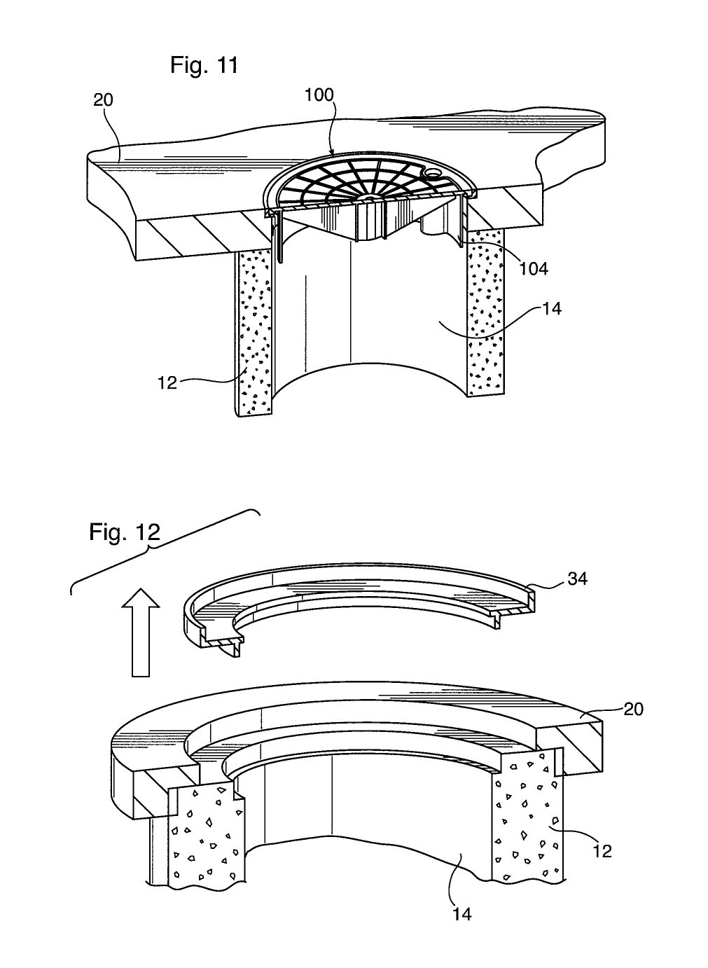

In accordance with another aspect of this invention, a method of reducing the instance of electrical shock emanating from a handwell is provided. In accordance with the method, an access cover 100 according to any of the proceeding embodiments is provided. The existing access cover (e.g., access cover 24) is removed (see FIGS. 8 and 9). The connected terminal ends of wires that are in the handwell are positioned inwardly of the position of depending wall 104 when access cover 100 is installed. If the lower surface 112 of the new access cover 100 has a raised central region 128, then the wires are preferably positioned beneath raised central region 128. Accordingly, the wires are preferably positioned above the position of lower end 150 of depending wall 104 when access cover 110 is installed so as to be inside the raised central region or dome shaped. As exemplified in FIGS. 10 and 11, using the alternate embodiment of FIG. 7, access cover 100 may then be positioned on handwell 10 such that depending wall 108 is positioned inwardly of the handwell (e.g., inwardly of depending wall 40 of liner ring 34).

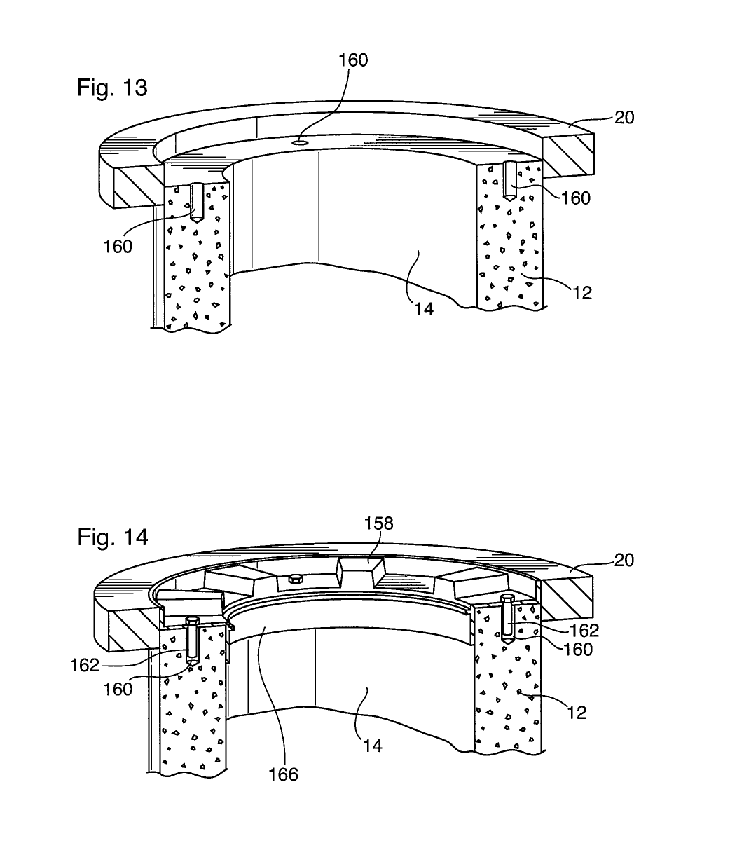

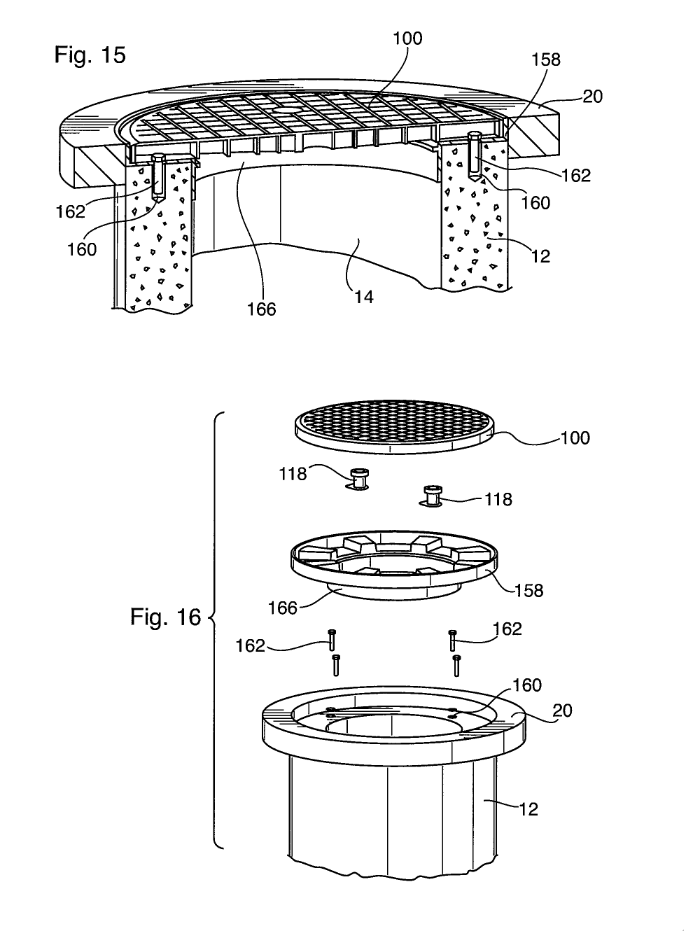

In an alternate embodiment, no liner ring 34 may be provided. Alternately, as exemplified in FIGS. 8, 9 and 12-15, a new liner ring 34 may be installed prior to the installation of access cover 100. According to this alternate embodiment, the existing access cover (e.g., access cover 24) is removed (see FIGS. 8 and 9). The existing liner ring 34 may be set in the concrete and liner ring 34 will have to be loosened to permit its removal (see FIG. 12). Alternately, if no liner ring 34 is present, the concrete may have to be broken to provide an opening for the new liner ring 34. The existing concrete may have to be ground to provide a position in which new liner ring 158 may be seated.

New liner ring 158 may be secured in position by any means known in the art, such as an adhesive, setting new liner ring 158 in wet concrete and mechanical fasteners 162. Accordingly, if mechanical fasteners 162 are used, optionally holes 160 may be provided for receiving mechanical fasteners 162 that secure new liner ring 158 in position. As exemplified, mechanical fasteners 162 comprise bolts. The bolts may be secured in position by an adhesive (e.g., an epoxy). Alternately, if new liner ring 158 is seated in wet concrete, then the head of the bolts may be set in the new concrete such that the threaded ends extend upwardly through openings provided in new liner ring 158. A threaded nut may then be used to secure new liner ring 158 in position. In a further alternate embodiment that is exemplified in FIG. 17, new liner ring 158 may be provided with barbs 164 that may be integrally molded with liner ring 158 and may be secured in openings 160 using an adhesive or set into wet concrete.

Finally, new access cover 100 may be set in position and secured in place.

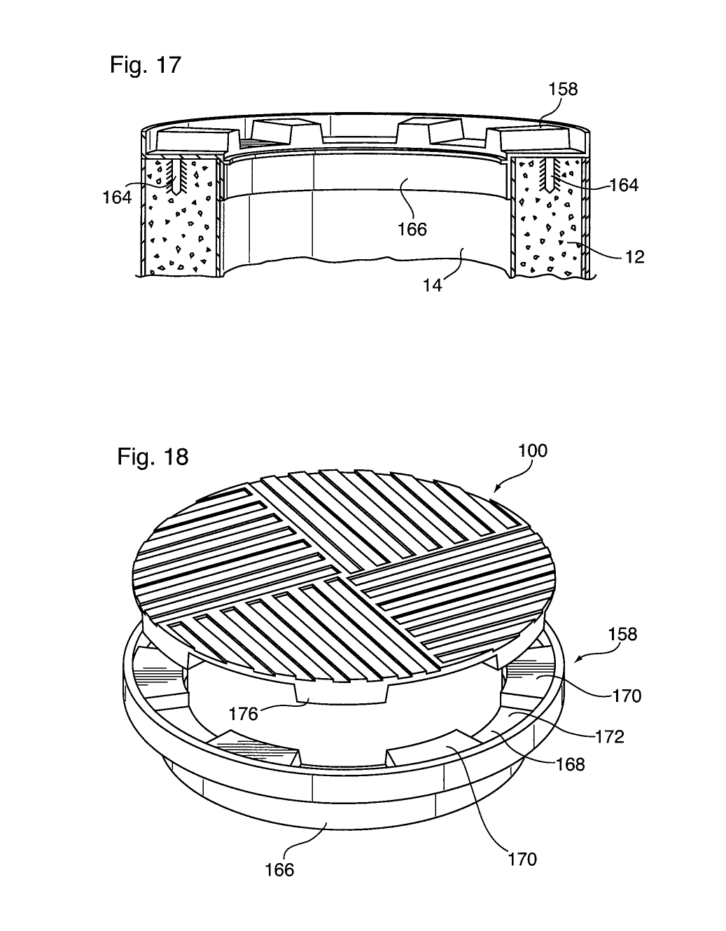

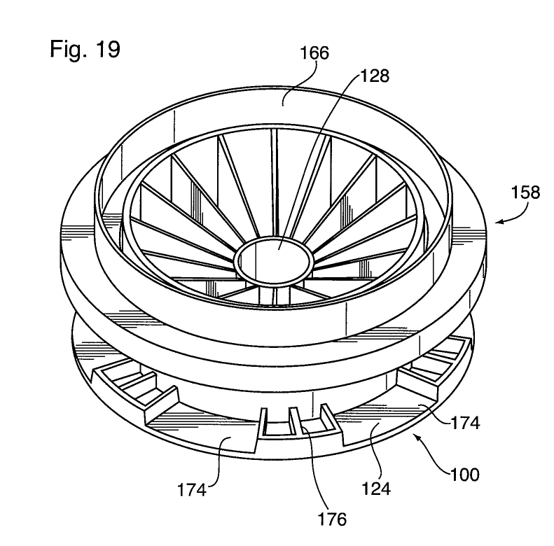

New liner ring 158 may be of any design, preferably, as exemplified in FIGS. 18 and 19, new liner ring 158 and access cover 100 may be configured such that access cover 100 is inhibited from rotational movement when seated on liner ring 158. Accordingly, lower surface 124 of perimeter 114 of access cover 100 and upper surface 168 of new liner ring 158 may have inter-engaging or inter fitting members. As exemplified in FIG. 18, upper surface 168 of new liner ring 158 is optionally provided with at least one and, preferably, a plurality of raised portions 170. Recesses 172 are provided between adjacent raised portions 170. As lower surface 124 is configured so as to seat on upper surface 168, lower surface 124 may be provided with mating recesses 174 and raised portions 176 on lower surface 124 that inter fit with recesses 172 and raised portions 170 of upper surface 168 (see for example FIG. 19). These recesses and raised portions provide interfitting members, which inhibit the rotational motion of access cover 100 with respect to liner ring 158. It will be appreciated that various other structures may be utilizes for the interfitting members such as pins and holes, guide ways and by the shape itself.

Various apparatus or methods are described above to provide an example of each claimed invention. No example described above limits any claimed invention and any claimed invention may cover processes or apparatuses that are not described above. The claimed inventions are not limited to apparatuses of processes having all the features of any one apparatus or process described above or to features common to multiple or any of the apparatuses described above.

1. An access cover for a hand well or hand hole comprising:
(a) a top member having an upper surface, a lower surface and a perimeter, the lower surface being configured to inhibit radial outward migration of wires positioned in the hand well; and,
(b) a depending wall extending away from the lower surface of the top member and positioned inwardly from the perimeter, whereby a portion of the top member radially outwardly of the perimeter comprises a flange that extends outwardly from the depending wall
wherein the top member and depending wall are constructed from an electrical insulating material.

2. The access cover of claim 1 wherein the lower surface has a raised central portion.

3. The access cover of claim 2 wherein the lower surface is dome shaped.

4. The access cover of claim 1 wherein the lower surface comprises a plurality of depending ribs, the ribs having a radial inner end and a radial outer end.

5. The access cover of claim 4 wherein the radial inner end of the ribs have a height and the radial outer end of the ribs have an increased height.

6. The access cover of claim 4 wherein the top member, the depending wall and the ribs are integrally molded.

7. The access cover of claim 1 wherein the access cover is integrally molded.

8. The access cover of claim 1 further comprising an opening provided at a location in the top member for passage therethrough of a securing member.

9. The access cover of claim 8 wherein the opening is provided in the flange and the depending wall is recessed inwardly at the location.

10. The access cover of claim 1 wherein the access cover is constructed from a thermoplastic or thermoset material.

11. The access cover of claim 1 wherein the access cover is constructed from polyurethane or polyamide.

12. The access cover of claim 1 wherein the upper surface is generally flat and is provided with traction members.

13. A method of reducing the incidence of electrical shock emanating from a hand well comprising:
(a) positioning terminal ends of electrical wires towards the centre of the hand well;
(b) providing an access cover constructed from an electrical insulating material and comprising:
(i) a top member having an upper surface, a lower surface and a perimeter, the lower surface being configured to inhibit radial outward migration of wires positioned in the hand well; and,
(ii) a depending wall extending away from the lower surface of the top member; and,
(c) positioning the access cover on the hand well whereby the depending wall is positioned inwardly of the hand well and the terminal ends are positioned inwardly of the depending wall.

14. The method of claim 13 wherein the lower surface has a raised central region and the method further comprises positioning the terminal ends in the raised central region.

15. The method of claim 13 further comprises securing the access cover to the hand well at a location exterior to the depending wall.

16. The method of claim 15 further comprising providing an inward recess of the depending wall at the location.

17. The method of claim 13 further comprising constructing the access cover from a thermoplastic or thermoset material.

18. The method of claim 13 further comprising constructing the access cover from polyurethane or polyamide.

19. The method of claim 13 further comprising removing an existing cover and installing a liner ring constructed from an electrical insulating material prior to step (c).

20. The method of claim 19 further comprising providing the liner ring and the access cover with inter fitting members.

21. An access cover for a hand well or hand hole comprising a top member having an upper surface, a lower surface and a perimeter, the lower surface being configured to inhibit radial outward migration of wires positioned in the hand well, wherein the top member is constructed from an electrical insulating material.

22. The access cover of claim 21 wherein the lower surface has a raised central portion.

23. The access cover of claim 22 wherein the lower surface is dome shaped.

24. The access cover of claim 21 wherein the lower surface comprises a plurality of depending ribs, the ribs having a radial inner end and a radial outer end.

25. The access cover of claim 25 wherein the radial inner end of the ribs have a height and the radial outer end of the ribs have an increased height.

26. The access cover of claim 25 wherein the top member and the ribs are integrally molded.

27. The access cover of claim 21 wherein the access cover is integrally molded.

28. The access cover of claim 21 further comprising an opening provided at a location in the top member for passage therethrough of a securing member.

29. The access cover of claim 28 wherein the opening is provided in a flange.

30. The access cover of claim 21 wherein the access cover is constructed from a thermoplastic or thermoset material.

31. The access cover of claim 21 wherein the access cover is constructed from polyurethane or polyamide.

32. The access cover of claim 21 wherein the upper surface is generally flat and is provided with traction members.

33. A method of reducing the incidence of electrical shock emanating from a hand well comprising:
(a) positioning terminal ends of electrical wires towards the centre of the hand well;
(b) providing an access cover constructed from an electrical insulating material and comprising a top member having an upper surface, a lower surface and a perimeter, the lower surface being configured to inhibit radial outward migration of wires positioned in the hand well; and,
(c) positioning the access cover on the hand well.

34. The method of claim 33 wherein the lower surface has a raised central region and the method further comprises positioning the terminal ends in the raised central region.

35. The method of claim 33 further comprising constructing the access cover from a thermoplastic or thermoset material.

36. The method of claim 33 further comprising constructing the access cover from polyurethane or polyamide.

37. The method of claim 33 further comprising removing an existing cover and installing a liner ring constructed from an electrical insulating material prior to step (c).

38. The method of claim 37 further comprising providing the liner ring and the access cover with inter fitting members.
